(19) United States
(12) Patent Application Publication
(10) Pub. No.: US 2022/0122813 A1
(43) Pub. Date: Apr. 21, 2022

(54) SUBSTRATE PROCESSING SYSTEM, CONTROL METHOD, AND CONTROL PROGRAM

(71) Applicant: TOKYO ELECTRON LIMITED, Tokyo (JP)

(72) Inventors: Mohd Fairuz BIN BUDIMAN, Miyagi (JP); Shu KINO, Miyagi (JP); Joji TAKAYOSHI, Miyagi (JP)

(73) Assignee: TOKYO ELECTRON LIMITED, Tokyo (JP)

(21) Appl. No.: 17/501,986

(22) Filed: Oct. 14, 2021

(30) Foreign Application Priority Data
Oct. 16, 2020 (JP) 2020-174815

(51) Int. Cl. H01J 37/32; H01L 21/67

(52) U.S. Cl. CPC H01J 37/32642; H01J 37/32027; H01L 21/67069; H01J 37/32174; H01J 37/32743

(57) ABSTRACT

There is provided a substrate processing system. The system comprises: a substrate processing device having a processing container configured to perform processing of a substrate, and a direct current (DC) power source configured to apply a DC voltage to a specific part in the processing container; and a controller configured to control the substrate processing device. A process performed by the controller includes a process of acquiring desired process conditions and a real value of the DC voltage measured during processing of the substrate based on the process conditions, and a process of creating a regression analysis equation which calculates an estimated value of the DC voltage using a plurality of conditions among the process conditions as explanatory variables based on the acquired process conditions and real value of the DC voltages.

### CROSS-REFERENCE TO RELATED APPLICATIONS

This application claims priority to Japanese Patent Application No. 2020-174815, filed on Oct. 16, 2020, the entire contents of which are incorporated herein by reference.

### TECHNICAL FIELD

The present disclosure relates to a substrate processing system, a control method, and a control program.

### BACKGROUND

In Japanese Patent Application Publication No. 2019-216164, a power level of bias high frequency power corresponding to a designated value of a direct current (DC) potential of a focus ring is specified using a relationship between a specific power level of the bias high frequency power and the DC potential of the focus ring generated by supplying the bias high frequency power to a lower electrode.

### SUMMARY

The present disclosure is directed to providing a technology capable of preventing application of a voltage outside an allowable range to a specific part of a substrate processing device in advance.

In accordance with an aspect of the present disclosure, there is provided a substrate processing system. The system comprises: a substrate processing device having a processing container configured to perform processing of a substrate, and a direct current (DC) power source configured to apply a DC voltage to a specific part in the processing container; and a controller configured to control the substrate processing device. A process performed by the controller includes a process of acquiring desired process conditions and a real value of the DC voltage measured during processing of the substrate based on the process conditions, and a process of creating a regression analysis equation which calculates an estimated value of the DC voltage using a plurality of conditions among the process conditions as explanatory variables based on the acquired process conditions and real value of the DC voltages.

### BRIEF DESCRIPTION OF THE DRAWINGS

FIG. 1 is a view illustrating an example of a substrate processing system according to an embodiment.

FIG. 2 is a schematic cross-sectional view illustrating an example of a substrate processing device and a hardware (HW) configuration of an equipment controller (EC) according to the embodiment.

FIG. 3 is a view illustrating an example of a hardware configuration of an analysis server according to the embodiment.

FIG. 4 is a view for describing the inclination of a tilting angle.

FIGS. 5A and 5B are views illustrating a change amount of a sheath thickness according to the embodiment compared with Reference Example.

FIG. 6 is a view illustrating an example of process conditions and an FR V_{dc} during substrate processing according to the embodiment.

FIG. 7 is a view illustrating an example of a relationship between the process conditions and the FR V_{dc} according to the embodiment.

FIGS. 8A, 8B, 8C, and 8D are views illustrating an example of the relationship between the process conditions and the FR V_{dc} according to the embodiment for each gas type.

FIG. 9 is a view illustrating an example of a functional configuration of the analysis server according to the embodiment.

FIG. 10 is a view illustrating an example of a relationship between an estimated value and a real value of the FR V_{dc} according to the embodiment.

FIG. 11 is a flowchart illustrating an example of a control method (recipe determination processing) according to the embodiment.

FIG. 12 is a flowchart illustrating details of the determination processing shown in FIG. 11.

### DETAILED DESCRIPTION

Hereinafter, an embodiment of the present disclosure will be described with reference to the accompanying drawings. In each drawing, the same numeral is granted to the same component, and overlapping descriptions will be omitted.

[Substrate Processing System]

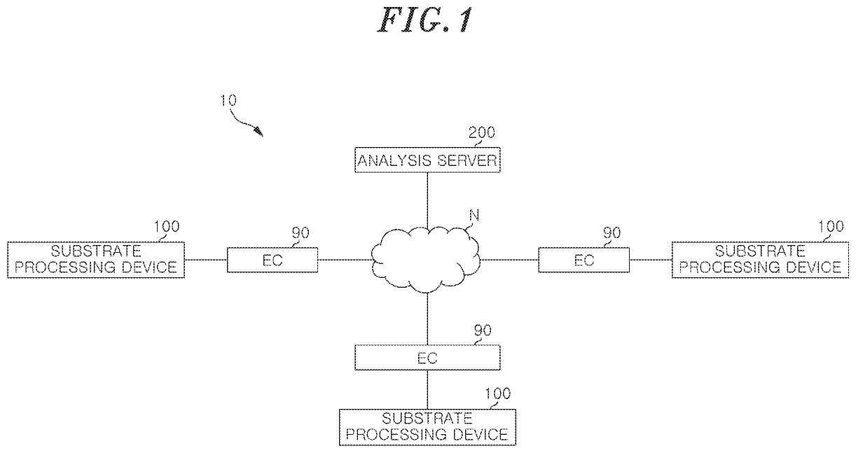

First, a substrate processing system 10 according to an embodiment will be described with reference to FIG. 1. FIG. 1 is a view illustrating an example of the substrate processing system 10 according to the embodiment. The substrate processing system 10 has a substrate processing device 100 which performs substrate processing, an equipment controller (EC) 90 which controls the substrate processing device 100, and an analysis server 200 which receives information from the EC 90 and analyzes the information.

The substrate processing device 100 may be a plasma etching device, a plasma chemical vapor deposition (CVD) device, or other devices capable of performing the substrate processing.

The EC 90 is provided for every substrate processing device 100. Each EC 90 controls the substrate processing device 100 connected thereto. Each EC 90 is connected to the analysis server 200 through a network N. Although three substrate processing devices 100 and three ECs 90 are shown in FIG. 1, the present disclosure is not limited thereto. One or more substrate processing devices 100 and one or more ECs 90 may be connected to the analysis server 200 through the network N. The EC 90 may be implemented by a cloud computer.

The EC 90 accumulates process conditions of the substrate processing performed in the substrate processing device 100 and a real value of information on a result of performing the substrate processing according to the process conditions (for example, a direct current (DC) voltage applied to an edge ring to be described later (also referred to as “FR V_{dc}”)). The analysis server 200 communicates with the EC 90, and receives the process conditions, and the information on the result of performing the substrate processing according to the process conditions from the EC 90.

The analysis server 200 calculates a regression analysis equation for calculating the estimated value of the DC voltage applied to the edge ring, based on the received information. The analysis server 200 predicts a recipe for applying the DC voltage outside an operation range or greater than or equal to a power rating to the edge ring, among created desired recipes, based on the estimated value of the DC voltage calculated based on the regression analysis equation. Accordingly, based on the predicted result, a warning is transmitted, destruction or rewriting of the recipe is demanded, and trouble such as abnormal discharge, process stop, or the like occurring due to application of the DC voltage outside the operation range or greater than or equal to the power rating is prevented in advance.

The number of analysis servers 200 may be one or plural. The analysis server 200 may be implemented by a cloud computer. Some or all of the functions of the analysis server 200 may be provided in the EC 90, and the EC 90 and the analysis server 200 may be an integrated device. The EC 90 and the analysis server 200 are an example of a control unit which controls the substrate processing device.

[Substrate Processing Device and Hardware Configuration of EC]

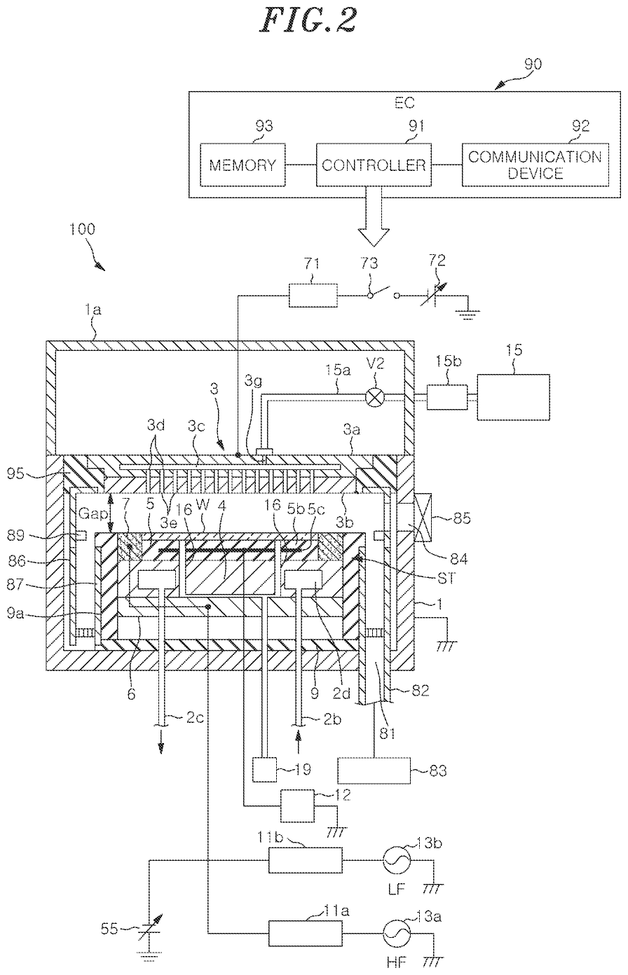

Next, an example of the substrate processing device 100 and the hardware configuration of the EC 90 according to the embodiment will be described with reference to FIG. 2. FIG. 2 is a schematic cross-sectional view illustrating an example of the substrate processing device 100 according to the embodiment, and a view illustrating an example of the hardware configuration of the EC 90.

The substrate processing device 100 has a processing container 1 with an electrically grounded potential. The processing container 1 has a cylindrical shape and is made of, for example, aluminum. In the processing container 1, a substrate support ST on which a substrate W is mounted is disposed. The substrate support ST has a first plate 4, a second plate 6, and an electrostatic chuck 5. The first plate 4 and the second plate 6 are made of, for example, aluminum. The electrostatic chuck 5 is made of, for example, a dielectric. The first plate 4 is provided on the second plate 6, and the electrostatic chuck 5 is provided on the first plate 4.

A ring-shaped member 7 made of, for example, silicon is provided around the substrate W. The ring-shaped member 7 is also referred to as a focus ring or an edge ring. A cylindrical outer circumferential member 9a is provided around the ring-shaped member 7, the first plate 4, and the second plate 6. The substrate support ST is disposed at a bottom portion of the processing container 1 through a support member 9 which connects lower end portions of the outer circumferential member 9a. The support member 9 and the outer circumferential member 9a are formed of, for example, quartz.

An electrode 5c in the electrostatic chuck 5 is interposed between a dielectric 5b and is connected to a DC power supply 12. When a DC voltage is applied to the electrode 5c from the DC power supply 12, a coulomb force is generated, and the substrate W is electrostatically adsorbed to the electrostatic chuck 5.

The first plate 4 has a flow path 2d therein. A heat exchange medium supplied from a chiller unit, for example, cooling water, circulates in the order of an inlet pipe 2b→the flow path 2d→an outlet pipe 2c. A heat transfer gas supply path 16 is formed in the substrate support ST. A heat transfer gas supply source 19 supplies a heat transfer gas to the heat transfer gas supply path 16, and introduces the heat transfer gas into a space between a lower surface of the substrate W and the electrostatic chuck 5. The heat transfer gas may be an inert gas such as helium gas (He), argon gas (Ar), or the like. A pin insertion path is provided in the substrate support ST, and the substrate W is raised/lowered during conveyance by a lifter pin which is inserted into and passes through the pin insertion path and moves up and down by a raising/lowering mechanism.

A first high frequency power supply 13a is electrically connected to the second plate 6 through a first matching unit 11a, and a second high frequency power supply 13b is electrically connected to the second plate 6 through a second matching unit 11b. The first high frequency power supply 13a applies high frequency power for plasma generation (also referred to as HF power) to the second plate 6. The second high frequency power supply 13b applies high frequency power for a bias voltage (also referred to as LF power) to the second plate 6. However, the high frequency power supplied from the second high frequency power supply 13b may be used for plasma generation. The high frequency power for a bias voltage has a lower frequency than that of the high frequency power for plasma generation and is used to draw ions into the substrate support ST.

The substrate processing device 100 further includes a DC power supply 55. The DC power supply 55 is connected to the second plate 6, and is electrically connected to the ring-shaped member 7 from the second plate 6 through the first plate 4. The DC power supply 55 supplies a DC voltage to the ring-shaped member 7 and controls a thickness of a sheath on the ring-shaped member 7. Control of the DC voltage applied to the ring-shaped member 7 is performed according to a consumption amount of the ring-shaped member 7.

An upper electrode 3 opposite the substrate support ST is provided above the substrate support ST. The upper electrode 3 has an electrode plate 3b and an electrode support 3a. A ring-shaped insulating member 95 which supports the upper electrode 3 is provided around the upper electrode 3, and an upper opening of the processing container 1 is blocked by the upper electrode 3 and the insulating member 95. The electrode support 3a is made of a conductive material, for example, aluminum with an anodized surface, and the electrode plate 3b is detachably supported under the electrode support 3a. The electrode plate 3b is formed of silicon or a silicon-containing material.

A gas diffusion chamber 3c and a gas introduction port 3g for introducing a processing gas into the gas diffusion chamber 3c are formed in the electrode support 3a. A gas supply pipe 15a is connected to the gas introduction port 3g. A gas supply part 15, a mass flow controller (MFC) 15b, and an on/off valve V2 are connected to the gas supply pipe 15a in this order, and the processing gas is supplied to the upper electrode 3 from the gas supply part 15 through the gas supply pipe 15a. The on/off valve V2 and the MFC 15b control an on state and an off state of the gas and a gas flow rate.

A plurality of gas flow holes 3d are formed in the lower portion of the gas diffusion chamber 3c toward the inside of the processing container 1 and communicate with gas introduction holes 3e formed in the electrode plate 3b. The processing gas is supplied in the form of a shower from the gas introduction holes 3e into the processing container 1 through the gas diffusion chamber 3c and the gas flow holes 3d.

A DC power supply 72 is connected to the upper electrode 3 through a low-pass filter (LPF) 71, and application and stop of the application of a DC voltage from the DC power supply 72 are controlled by a switch 73. When high-frequency power is applied from the first high frequency power supply 13a and the second high frequency power supply 13b to the substrate support ST to convert the processing gas into plasma, the switch 73 is turned on as necessary, and a desired DC voltage is applied to the upper electrode 3.

A cylindrical ground conductor 1a is provided to extend upward from a sidewall of the processing container 1 above the height position of the upper electrode 3. The cylindrical ground conductor 1a has a ceiling wall at an upper portion thereof.

An exhaust port 81 is formed at a lower portion of the processing container 1, and an exhaust device 83 is connected to the exhaust port 81 through an exhaust pipe 82. The exhaust device 83 has a vacuum pump, and by operating the vacuum pump, a pressure in the processing container 1 is reduced to a predetermined degree of vacuum. A loading/unloading port 84 of the substrate W is provided in the sidewall in the processing container 1, and the loading/unloading port 84 may be opened and closed by a gate valve 85.

A deposit shield 86 is detachably provided along an inner wall of a side portion of the processing container 1. Further, a deposit shield 87 is detachably provided along the outer circumferential member 9a. The deposit shields 86 and 87 prevent an etching by-product (deposit) from adhering to the inner wall of the processing container 1 and the outer circumferential member 9a. A conductive member (GND block) 89 to which an electric potential with respect to the ground is controllably connected is provided at a position substantially the same height as the substrate W of the deposit shield 86, thereby preventing abnormal discharge.

The substrate processing device 100 is controlled by the EC 90. The EC 90 is provided with a controller 91 which controls each part of the substrate processing device 100, a communication device 92, and a memory 93.

The memory 93 stores a control program (software) which causes the controller 91 to execute various processes executed in the substrate processing device 100, and a recipe in which process conditions and a process order are stored. The communication device 92 is a communication device such as a network card or the like which controls communication.

The controller 91 calls an arbitrary recipe from the memory 93 and executes the arbitrary recipe. Accordingly, the substrate processing is performed in the substrate processing device 100 based on control of the EC 90. As the control program and recipe for performing desired substrate processing, those stored in a computer-readable computer storage medium such as the controller 91 or the like may be used. Further, the control program and recipe for performing the desired substrate processing may be transmitted from another apparatus through a network to be acquired online and used. As a storage medium, for example, a hard disk, a CD, a flexible disk, a semiconductor memory and the like may be mentioned.

[Hardware Configuration of Analysis Server]

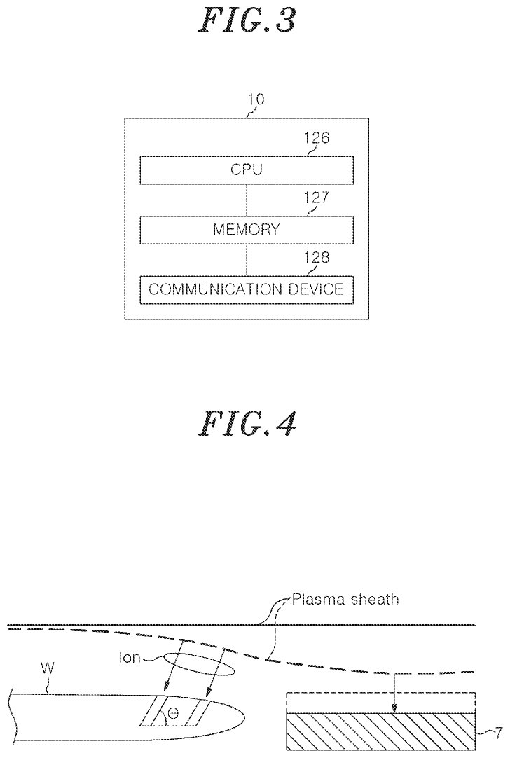

Next, the hardware configuration of the analysis server 200 will be described with reference to FIG. 3. FIG. 3 is a view illustrating an example of the hardware configuration of the analysis server 200 according to the embodiment. The analysis server 200 has a central processing unit (CPU) 126, a memory 127, and a communication device 128. The CPU 126 creates a regression analysis equation for calculating the estimated value (also referred to as estimated V_{dc}) of the DC voltage applied to the ring-shaped member 7 around the substrate W, or performs various calculations. The memory 127 is, for example, a storage medium in the analysis server 200 directly accessible to the CPU 126. The communication device 128 is a communication device such as a network card or the like which controls communication.

The memory 127 is realized by various memories such as a random-access memory (RAM), a read only memory (ROM), and the like. The analysis server 200 provides the created regression analysis equation to the EC 90, and allows the EC 90 to control the substrate processing device 100.

[Edge Ring Consumption]

Consumption of the ring-shaped member 7 will be described with reference to FIG. 4. FIG. 4 is a view for describing the inclination of a tilting angle. The ring-shaped member 7 is exposed to plasma during the processing of the substrate W, and is consumed. For example, in the case in which etching is performed on the substrate W, when the ring-shaped member 7 is a new product, as shown by a solid line in FIG. 4, the ring-shaped member 7 is disposed so that a plasma sheath on the ring-shaped member 7 (hereinafter referred to as a “sheath”) has the same height as a sheath on the substrate W. In this state, ions in the plasma are vertically incident on the substrate W, and an etching target film on the substrate W is vertically etched.

When the ring-shaped member 7 is consumed, the height of the sheath on the ring-shaped member 7 becomes lower than the height of the sheath on the substrate W, as shown by a dotted line in FIG. 4. As a result, in a region of an outer circumferential end portion of the substrate W, the ions in the plasma are obliquely incident, and a concave portion formed in the etching target film on the substrate W is obliquely inclined. The tilting angle at this time is represented as θ. A change amount of the tilting angle θ changes according to an incident angle of the ion. In other words, the change amount of the tilting angle θ is changed by the sheath thickness on the ring-shaped member 7, that is, a consumption amount of the ring-shaped member 7.

In order to make the incident angle of the ion vertical and form an etching concave portion in a vertical shape, the DC power supply 55 applies the DC voltage to the ring-shaped member 7 according to the consumption amount of the ring-shaped member 7, and the sheath thickness on the ring-shaped member 7 is controlled. Accordingly, the etching concave portion may have the vertical shape by adjusting the sheath on the ring-shaped member 7 to the same height as the sheath on the substrate W, and controlling the tilting angle θ to about 90°.

However, in the case of applying the DC voltage to the ring-shaped member 7 and the case of not applying the DC voltage to the ring-shaped member 7, the magnitude of a high-frequency current applied to the second plate 6 from the first high frequency power supply 13a and the second high frequency power supply 13b and flowing in a plasma generation space through the first plate 4 changes. For example, when no direct current voltage is applied to the ring-shaped member 7, the high frequency current flowing on a center side of the substrate W and the high frequency current flowing on an edge side have substantially the same magnitude. On the other hand, when the DC voltage is applied to the ring-shaped member 7, the high frequency current flowing on the center side of the substrate W becomes relatively larger. Accordingly, a plasma density above the center and a middle side of the substrate W becomes high.

For this problem, in the substrate processing device 100 according to the present embodiment, the following X % display method is proposed as a method of uniformly controlling the direct current voltage applied to the ring-shaped member 7 while minimizing a shift of a plasma characteristic given to the entire substrate.

When the sheath thickness on the ring-shaped member 7 is t, Equation (1) for calculating the sheath thickness t is as follows.

$$\begin{matrix}[ Equation 1 ] & \\ t = \frac{2}{3} exp ( \frac{1}{4} ) {( \frac{{ɛ}_{0}}{{n}_{i}} )}^{\frac{1}{2}} {{V}_{dc}^{\frac{3}{4}} ( \frac{2}{{ekT}_{e}} )}^{\frac{1}{4}} & Equation ( 1 )\end{matrix}$$

Here, V_{dc} is a DC voltage applied to the ring-shaped member 7. nᵢ is an ion density, and the ion density nᵢ is equal to an electron density Ne of the plasma and the plasma density. Tₑ is an electron temperature of the plasma. ε₀ is permittivity of vacuum, e is an elementary charge, and k is a Boltzmann constant. ε₀, e, and k are constants. Among variables included in Equation (1), the ion density nᵢ, V_{dc}, and electron temperature Tₑ of the plasma change depending on the process conditions.

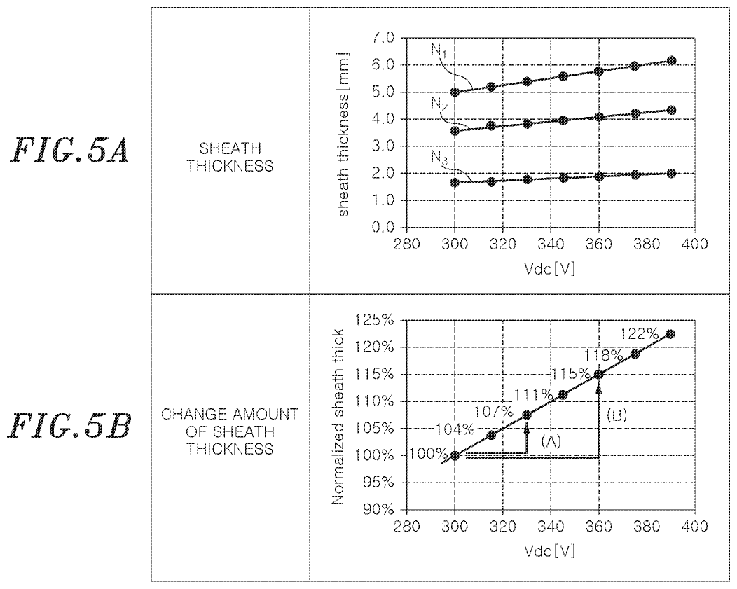

Accordingly, the sheath thickness t represented by Equation (1) becomes different thicknesses according to the V_{dc} and the ion density nᵢ. Further, here, the V_{dc} represents a potential of the ring-shaped member 7 and is equal to a potential of the substrate. For example, the sheath thickness t represented by a vertical axis of a graph in FIG. 5A is different according to the V_{dc} represented by a horizontal axis of the graph and values of N1, N2, and N3 which are the ion densities nᵢ of curved lines on the graph.

In the present embodiment, the change amount of the sheath thickness t is used as a parameter used for controlling the DC voltage applied to the ring-shaped member 7. The change amount {(tₓ−t)/t} of the sheath thickness is converted as in Equation (2) based on Equation (1).

$$\begin{matrix}[ Equation 2 ] & \\ \frac{{t}_{x} - t}{t} \times 100 = a \times 2 {{V}_{dc} ( 1 + \frac{X}{100} )}^{\frac{3}{4}} & Equation ( 2 )\end{matrix}$$

{(tₓ−t)/t}×100 represents a change amount (%) of the sheath thickness. a included in Equation (2) is a proportional constant. Among variables included in Equation (2), when the sheath thickness changes by a predetermined percent, X represents how many percentages of the DC voltage applied to the ring-shaped member 7 needs to be incremented to maintain the sheath thickness at the original thickness. X is a parameter for DC voltage control (hereinafter, also referred to as “parameter X”).

That is, the change amount of the sheath thickness {(tₓ−t)/t}×100 represents how many percent of the sheath thickness changes when the DC voltage applied to the ring-shaped member 7 is applied in increments of X %. The right side (1+X/100) of Equation (2) is the sum of “1” for self-bias and “X/100” which is 1/100 of X % for the DC voltage applied to the ring-shaped member 7, and the potential of the ring-shaped member 7 is calculated by multiplying this value by V_{dc}. In Equation (2), when V_{dc} (1+X/100), which is the potential of the ring-shaped member 7, is controlled, the change amount (tₓ−t)/t of the sheath thickness may be uniformly controlled regardless of the ion density nᵢ.

Accordingly, in the present embodiment, as shown in FIG. 5B, the change amount {(tₓ−t)/t} of the sheath thickness is controlled using Equation (2). For example, in FIG. 5A shown as a reference example, when the V_{dc} and/or the ion densities nᵢ change, the sheath thickness changes. For example, when the ion densities nᵢ are N1, N2, and N3, the sheath thickness is changing.

On the other hand, in the present embodiment, as shown in FIG. 5B, the change amount of the sheath thickness when the sheath thickness when the V_{dc} is 300 [V] is 100% is represented. An arrow of (A) in the drawing represents a case in which 10% is substituted for the X in Equation (2), that is, a case in which the V_{dc} increases by 10% from an initial value of 300 [V] and thus is controlled to 330 [V]. Then, in this case, the arrow of (A) represents that the change amount of the sheath thickness increases by 11% from the initial value of the sheath thickness and thus the sheath thickness becomes 111%. An arrow of (B) in the drawing represents that the change amount of the sheath thickness increases by 18% from the initial value of the sheath thickness, and thus the sheath thickness becomes 118% when 20% is substituted for the X in Equation (2), that is, when the V_{dc} is controlled from the initial value of 300 [V] to 360 [V].

That is, in the present embodiment, the change amount {(tₓ−t)/t} of the sheath thickness is controlled using Equation (2). Accordingly, by controlling the X percent of the DC voltage applied to the ring-shaped member 7, the change amount of the sheath thickness with respect to the DC voltage applied to the ring-shaped member 7 may be controlled regardless of the change of the plasma density (ion density) even when the plasma density (ion density) changes.

However, a potential of the plasma (ion density or the like) changes according to the process conditions.

Accordingly, for example, when the DC voltage applied to the ring-shaped member 7 is controlled to be increased by 10% from the initial value to be applied, the DC voltage actually applied to the ring-shaped member 7 changes according to the process conditions. As a result, there is a possibility in that a DC voltage greater than or equal to the power rating of the DC power supply 55 is applied to the ring-shaped member 7.

Accordingly, the analysis server 200 and the EC 90 execute a control method according to the present embodiment to prevent trouble such as abnormal discharge, process stop, or the like generated in the substrate processing device 100 in advance so that the DC voltage outside the operation range or greater than or equal to the power rating is not applied.

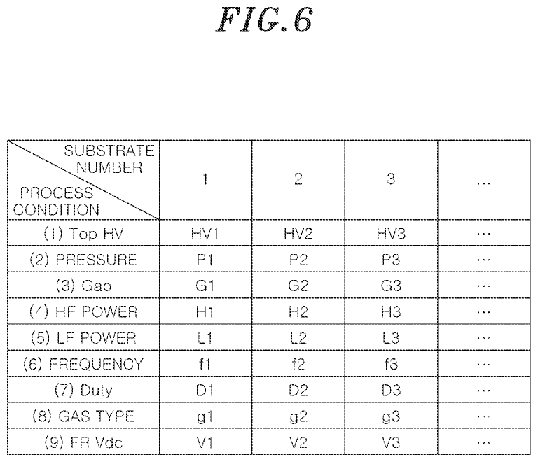

In the control method according to the present embodiment, information used when creating the regression analysis equation for calculating the estimated V_{dc} will be described with reference to FIG. 6. FIG. 6 is a view illustrating an example of process conditions and an FR V_{dc} during substrate processing according to the embodiment. The information shown in FIG. 6 is accumulated in the memory 93 of the EC 90 according to execution of the substrate processing.

The information shown in FIG. 6 is an example of the process conditions, and is not limited thereto. In this example, as the process conditions used for the substrate processing, (1) a top high voltage (HV), (2) a pressure, (3) gap, (4) high frequency (HF) power, (5) low frequency (LF) power, (6) a frequency of HF or frequency of LF, (7) duty, and (8) the type of gas are stored. Further, (9) an FR V_{dc} refers to a DC voltage actually applied to the ring-shaped member 7 for each substrate number when the substrate is processed under the process conditions of (1) to (8), and here, the FR Vdc represents the real value of the DC voltage (also referred to as a real V_{dc}).

(1) The top HV is a DC voltage applied from the DC power supply 72 to the upper electrode 3. (2) The pressure is a pressure in the processing container. (3) The gap is a distance between the upper electrode 3 and the substrate support ST, as shown in FIG. 2. (7) The duty is a duty ratio in the case in which the HF power or LF power is a pulse wave. Further, although the HF power is applied to the substrate support ST in the example in FIG. 2, the present disclosure is not limited thereto, and the HF power may be applied to the upper electrode 3.

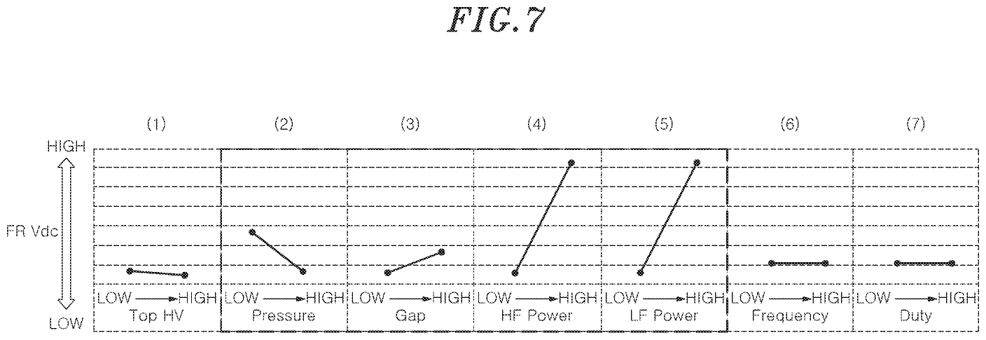

FIG. 7 is a view illustrating an example of a relationship between the process conditions (1) to (7) and the FR V_{dc} (real V_{dc}) shown in FIG. 6. In FIG. 7, a horizontal axis shows values of the process conditions (1) to (7) for the plurality of substrates shown in FIG. 6, and a vertical axis shows the FR V_{dc} (real V_{dc}).

As a result, it was found that the process conditions for which the sensitivity to the FR V_{dc} is high, that is, the change amount of the FR V_{dc} is large were (2) the pressure, (3) the gap, (4) the HF power, and (5) the LF power. In the other process conditions (1), (6), and (7), it was found that the change amount of the FR V_{dc} was small and the sensitivity to the FR V_{dc} was low.

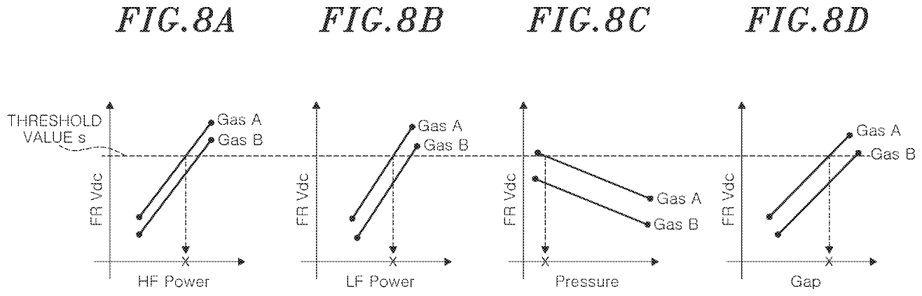

FIG. 8 is a view illustrating an example of the relationship of the FR V_{dc} (real V_{dc}) for types A and B of the gas with respect to the HF power in FIG. 8A, the LF power in FIG. 8B, the pressure in FIG. 8C, and the gap in FIG. 8D which are four process conditions in which the change amount of the FR V_{dc} extracted in FIG. 7 is large.

According to this, for the four process conditions (FIG. 8A) the HF power, (FIG. 8B) the LF power, (FIG. 8C) the pressure, and (FIG. 8D) the gap, it was found that the change amount of the FR V_{dc} was substantially the same for any one of the gas types A and B.

From the above, the analysis server 200 uses a plurality of conditions among the process conditions as explanatory variables to create the regression analysis equation which calculates the estimated value (estimated V_{dc}) of the DC voltage based on the process conditions transmitted from the EP 90 and the real value (real V_{dc}) of the DC voltage. As the plurality of conditions used as the explanatory variables, conditions with a large change amount of the FR V_{dc} among the process conditions are used.

[Function of Analysis Server]

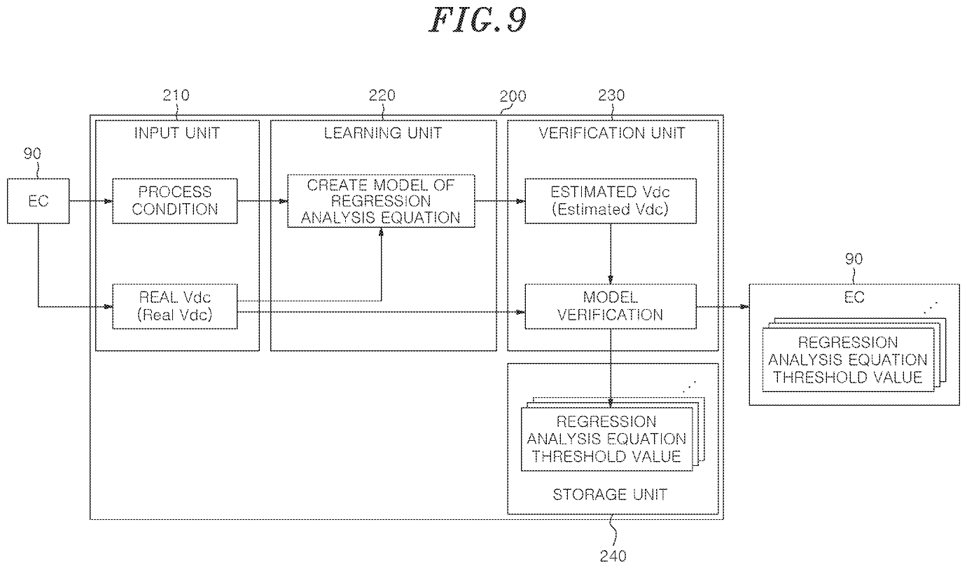

Next, the function of the analysis server 200 which creates the regression analysis equation for calculating the estimated V_{dc} will be described with reference to FIG. 9. FIG. 9 is a view illustrating an example of a functional configuration of the analysis server 200 according to the embodiment. The analysis server 200 includes an input unit 210, a learning unit 220, a verification unit 230, and a storage unit 240.

The input unit 210 inputs the process conditions and the real value (real V_{dc}) of the FR V_{dc} from the EC 90. The input process conditions and real V_{dc} are stored in the memory 127 in the analysis server 200.

The learning unit 220 creates a learning model of the regression analysis equation using the input process conditions and real V_{dc}. The learning model of the regression analysis equation is an equation for calculating the estimated value (the estimated V_{dc}) of the FR V_{dc}.

The learning unit 220 first extracts the explanatory variables from the process conditions. The explanatory variable is a variable used in the regression analysis equation, and is a condition in which the change amount of the FR V_{dc} (real V_{dc}) is large among the process conditions.

The learning unit 220 extracts, as the explanatory variables, the four conditions, that is, the HF power (FIG. 8A), the LF power (FIG. 8B), the pressure (FIG. 8C), and the gap (FIG. 8D) in which the change amount of the FR V_{dc} (real V_{dc}) is large among the process conditions. However, the learning unit 220 may extract other conditions from the process conditions as the explanatory variables. Another example of the explanatory variable may be a mode of the RF (whether HF and/or LF is a pulsed wave or a continuous wave). The top HV may be used as the explanatory variable. A type of substrate may be used as the explanatory variable. That is, as the explanatory variables those having a high contribution degree when calculating the estimated value of the FR V_{dc} may be extracted.

The learning unit 220 may automatically extract the explanatory variables based on the information showing the relationship between the process conditions and the FR V_{dc} (real V_{dc}) in FIG. 7 as an example. The learning unit 220 uses each extracted explanatory variable, inputs the explanatory variables into a preset regression analysis equation to optimize coefficients of the regression analysis equation, and automatically generates the regression analysis equation having the optimized coefficients. An example of the automatically generated regression analysis equation is shown in Equation (3).

[Equation 3]

Estimated Vdc=a*Press^{x1}+b*Gap^{x2}+c*HF^{x3}+d*LF^{x4}+e*LF^{x5}*Press^{x6}+f*Gap^{x7}*Press^{x8}+m Equation (3)

Equation (3) is an example of a regression analysis equation. In Equation (3), the estimated value (estimated V_{dc}) of the FR V_{dc} uses the four conditions (HF power, LF power, pressure, and gap) as variables to substitute the explanatory variables extracted from the process conditions input by the input unit 210 for each variable. Accordingly, coefficients a, b, c, d, e, and f of the explanatory variables and exponents x1, x2, x3, x4, x5, x6, x7, and x8 of the explanatory variables may be optimized.

For example, in Equation (3), first to fourth terms in which the explanatory variables of the four conditions (HF power, LF power, pressure, and gap) are independently present, respectively, and fifth and sixth terms in which two explanatory variables are multiplied are present, but terms constituting the regression analysis equation are not limited thereto.

In the example of the regression analysis equation shown in Equation (3), the learning unit 220 optimizes the coefficients a to d and the exponents x1 to x4 of the first to fourth terms which respectively represent the explanatory variables of the pressure, the gap, the HF power, and the LF power. Further, the learning unit 220 optimizes the coefficients e and f and the exponents x5 to x8 of the fifth term in which the explanatory variables of pressure and the LF power are multiplied and the sixth term in which the explanatory variables of the gap and the pressure are multiplied.

The optimized regression analysis equation (3) is verified by the verification unit 230. That is, the verification unit 230 verifies the model of the regression analysis equation for calculating the estimated V_{dc} transmitted from the learning unit 220.

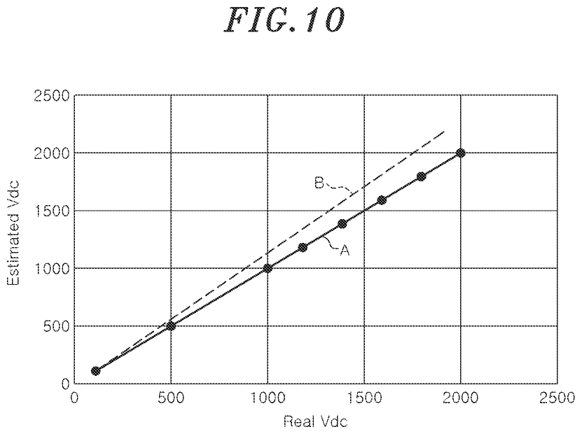

The verification unit 230 calculates the estimated V_{dc} using Equation (3) and compares the estimated V_{dc} with the real V_{dc} input by the input unit 210. FIG. 10 is a view illustrating an example of a relationship between estimated V_{dc} which is calculated based on the regression analysis equation according to the embodiment and the real V_{dc}. As shown in FIG. 10, when the estimated V_{dc} and the real V_{dc} show substantially the same value, the verification unit 230 approves Equation (3) as the model of the regression analysis equation, and stores Equation (3) in the storage unit 240. When the estimated V_{dc} shows a trend different from the real V_{dc}, the verification unit 230 does not approve Equation (3) as the regression analysis equation, and performs more learning or destroys the regression analysis equation without storing Equation (3) in the storage unit 240.

As an example of a verification method by the verification unit 230, as the four conditions (HF power, LF power, pressure, and gap) are used as variables, and all the data of the explanatory variables input by the input unit 210 is substituted for each variable, the coefficients and exponents of the explanatory variables are acquired, and the model of the regression analysis equation (referred to as model 1) is created. Next, using the four conditions (HF power, LF power, pressure, and gap) as variables, all the data of the explanatory variable input by the input unit 210 is divided into three divisions, which are a first third, a second third, and a last third, and is substituted into the regression analysis equation. Accordingly, a model of the regression analysis equation in which the coefficients and exponents are optimized using the first third (referred to as model 2), a model of the regression analysis equation in which the coefficients and exponents are optimized using the second third (referred to as model 3), and a model of the regression analysis equation in which the coefficients and exponents are optimized using the last third (referred to as model 4) are created. The verification unit 230 approves Equation (3) as the model of the regression analysis equation, and stores Equation (3) in the storage unit 240, when all of the created models 2 to 4 show substantially the same value as the model 1. In this verification, all the data of the explanatory variable was divided into 3 divisions, but the division is not limited to three. The verification unit 230 may divide all the data of the explanatory variable into an arbitrary number of 2 or more, and verify the validity of the regression analysis equation by the above method.

The storage unit 240 stores the approved regression analysis equation in association with a threshold value. The verification unit 230 sets the threshold value for each regression analysis equation. As shown in FIG. 8, the verification unit 230 changes a value of the explanatory variable on a horizontal axis set in the regression analysis equation, and when the estimated V_{dc} acquired by a result of calculating the FR V_{dc} becomes a threshold value s or more, it may be determined that the DC voltage applied to the shaped member 7 may be greater than or equal to the rating of the DC power supply 55. The threshold value s is preset to a value capable of determining whether the DC voltage applied to the ring-shaped member is greater than or equal to the rating of the DC power supply 55. As a result of verifying the validity of the regression analysis equation by the verification unit 230, the regression analysis equation whose validity is verified and the threshold value s for each regression analysis equation are transmitted to the EC 90, and are stored in the memory 93 of the EC 90. However, the regression analysis equation and the threshold value s corresponding to the regression analysis equation may be stored in one of the analysis server 200 or the EC 90. Further, the explanatory variable is not limited to, for example, the HF power and the LF power, and may be set for each mode of one of a pulse wave of the RF or a continuous wave of the RF. For example, the explanatory variable may be set for each mode of the pulse wave of HF power, the pulse wave of LF power, the continuous wave of HF power, and the continuous wave of LF power.

[Control Method: Recipe Determination Processing]

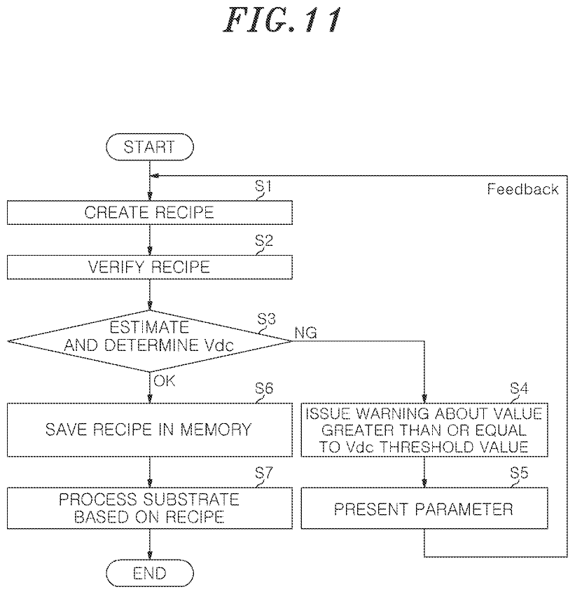

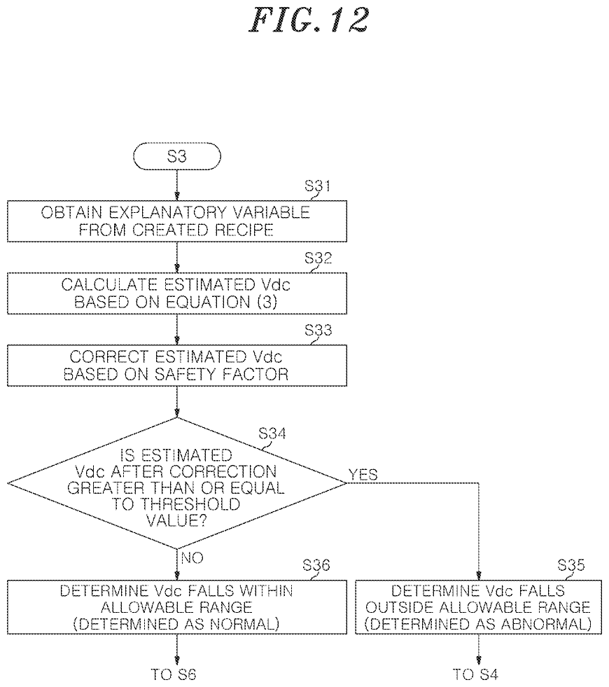

Next, a control method (recipe determination processing) according to the embodiment will be described with reference to FIGS. 11 and 12. FIG. 11 is a flowchart illustrating an example of the recipe determination processing according to the embodiment. FIG. 12 is a flowchart illustrating details of the determination processing shown in FIG. 11.

Before performing the processing in FIG. 11, the regression analysis equation and the threshold value s are stored in the memory 93 of the EC 90 and/or the memory 127 of the analysis server 200. In the following description, although an example in which the processing in FIGS. 11 and 12 is performed by the EC 90 is described, the processing may be executed by the analysis server 200.

In step S1 in FIG. 11, the EC 90 creates a recipe in which the process conditions for processing the substrate and an order of the process are set. Next, in step S2, the EC 90 verifies the created recipe.

In step S3, the EC 90 substitutes the conditions used as the explanatory variables among the process conditions set in the created recipe into the regression analysis equation (see Equation (3)) stored in the memory 127, and calculates the estimated V_{dc} from the regression analysis equation. Then, the EC 90 determines whether there is a possibility that the created recipe applies a DC voltage greater than or equal to the rating of the DC power supply 55 to the ring-shaped member 7 based on the estimated V_{dc} and the threshold value s. Details of the determination will be described later based on FIG. 12.

EC 90 determines “NG” in step S3 when it is determined that there is the possibility that the created recipe applies a DC voltage greater than or equal to the rating of the DC power supply 55 to the ring-shaped member 7. In this case, the EC 90 proceeds to step S4 without saving the recipe, and outputs a warning which indicates that the estimated V_{dc} is greater than or equal to the threshold value. Next, the EC 90 proceeds to step S5, and the explanatory variable input into the regression analysis equation is presented as a parameter. The warning output and presentation of the explanatory variable may be displayed and/or output as audio on the display of the EC 90, or displayed and/or output as audio on the display of a device such as a mobile terminal possessed by the operator or the like. Further, all explanatory variables may be output, and at least any one of the explanatory variables may be output.

Returning to step S1, the operator instructs a change in the value of at least one of the explanatory variables based on this display and/or audio output, and the EC 90 recreates a recipe according to an instruction, and in step S2, the created recipe is verified. The EC 90 may automatically change the value of at least any one of the explanatory variables without going through the instruction of the operator based on this display and/or audio output, and may recreate the recipe.

In step S3, the EC 90 inputs the conditions of the changed explanatory variable to the regression analysis equation stored in the memory 127, and calculates the estimated V_{dc} again. Then, the EC 90 determines whether there is the possibility that the created recipe applies a DC voltage greater than or equal to the rating of the DC power supply 55 to the ring-shaped member 7 based on the estimated V_{dc} and the threshold value s.

The EC 90 determines “OK” in step S3 when it is determined that there is no possibility that the created recipe applies a DC voltage greater than or equal to the rating of the DC power supply 55 to the ring-shaped member 7. In this case, the EC 90 saves the recipe in the memory 93 in step S6. The recipe may be stored in the memory 127. The EC 90 performs the substrate processing based on the saved recipe in step S7.

The detail of calculation and determination processing of the estimated V_{dc} of step S3 in FIG. 11 will be described with reference to FIG. 12. In the processing of step S3 shown in FIG. 12, first, in step S31, the EC 90 acquires a set value of the explanatory variable from the created recipe. Next, in step S32, the EC 90 substitutes the set value of the explanatory variable into the regression analysis equation (Equation (3), and calculates the estimated V_{dc}.

Next, in step S33, the EC 90 corrects the estimated V_{dc} based on a safety factor. The safety factor is a preset numerical value for a condition not used as the explanatory variable among the process conditions. For example, it is assumed that 10% is set as the safety factor for a type of gas not used as the explanatory variable.

In this case, the EC 90 uses a value acquired by multiplying the estimated V_{dc} by 1.1 as the corrected estimated V_{dc}. In the example in FIG. 10, the estimated V_{dc} after correction is represented as a straight line B with respect to the estimated V_{dc} represented as a straight line A calculated by the regression analysis equation of Equation (3). Further, the safety factor may differ according to the type of gas. In addition, the safety factor may not be set according to the type of gas. The estimated V_{dc} may be corrected based on at least one of safety factors which are set for the process conditions not used as the explanatory variables. When the safety factor is not set for any of the process conditions, step S33 may be omitted.

Next, in step S34, EC 90 determines whether the estimated V_{dc} after the correction is greater than or equal to the threshold value s stored in correspondence with the regression analysis equation. When it is determined that the estimated V_{dc} after the correction is greater than or equal to the threshold value s, the EC 90 proceeds to step S35 to determine that the V_{dc} deviates from the allowable range (determined as abnormal), and proceeds to step S4 in FIG. 11 to generate the warning.

Meanwhile, when it is determined that the estimated V_{dc} after the correction is smaller than the threshold value s, the EC 90 proceeds to step S36 to determine that the V_{dc} is within the allowable range (determined as normal), and proceeds to step S6 in FIG. 11 to save the created recipe in the memory 93.

In the above, the estimated V_{dc} is corrected using the safety factor set for the type of gas as an example, but the present disclosure is not limited thereto, and for example, the safety factor may be set to at least any one of the process conditions not used as the explanatory variables, such as a safety factor for the type of substrate processing device 100, or the like. Further, the safety factors may be set for all of the process conditions that are not used as explanatory variables. In this case, the estimated V_{dc} may be corrected based on all safety factors.

Like the above, in the present embodiment, the estimated V_{dc} or the estimated V_{dc} corrected by the safety factor is calculated from the regression analysis equation based on the regression analysis equation and the threshold value stored in the memory 93. Then, it is determined whether a DC voltage greater than or equal to the power rating is applied to the ring-shaped member 7 based on the calculated estimated V_{dc}. Accordingly, it is possible to determine whether or not to employ a desired recipe based on the determination result.

When the recipe is created, the control method according to the embodiment may be executed for the recipe created. Further, when the operator presses a start button of a processing start, the control method may be executed for the desired recipe. In addition, in relation to a type of substrate to be processed, the control method may be executed for the recipe used immediately before the processing of the desired type of substrate or at an arbitrary timing before the substrate processing. For example, when the recipe is recreated or the like, it is possible to determine whether or not to employ the recipe by executing the control method according to the embodiment with respect to the recipe. Accordingly, it is possible to eliminate the recipe in which an excessive DC voltage is applied to the ring-shaped member 7 to prevent related trouble in advance.

Further, the regression analysis equation and the threshold value s are saved in the memory, and then may be updated by performing more learning based on the process information (see FIG. 6) further accumulated by new substrate processing. The learning may be performed in the analysis server 200, may be performed in the EC 90, and may be performed in another device such as a cloud computer connected to the network N, an edge computer, or the like.

The explanatory variable used in the regression analysis equation is performed from viewpoints of both selection of a statistical parameter (see FIG. 7) and selection of a physical parameter. As an example of selection of the physical parameter, for example, based on Equation (1), a parameter physically affecting the sheath thickness t and the FR V_{dc} (for example, a plasma temperature Tₑ or the like) may be extracted as the explanatory variable. Another example of the selection of the physical parameter may be, for example, a case in which when increasing the RF power, electron energy increases, elastic collisions and ionization in the plasma proceed, and the FR V_{dc} increases so that the RF power is selected as the explanatory variable. Further, since the electron temperature Tₑ of the plasma becomes high and the FR V_{dc} rises as a pressure in the process container becomes a low pressure, the pressure may be selected as the explanatory variable. Further, when the gap becomes wider, since the distribution of the electron density of the plasma expands and the FR V_{dc} rises, the gap may be selected as the explanatory variable.

As described above, according to the substrate processing system, the control method, and the control program according to the embodiment, the estimated V_{dc} is calculated based on the set regression analysis equation. Then, based on the estimated V_{dc}, the warning may be given at the time of recipe creation or the like for the recipe in which the value of the DC voltage (FR V_{dc}) applied to the ring-shaped member 7 can be greater than or equal to the threshold value s. Accordingly, it is possible to prevent application of a voltage outside the allowable range greater than or equal to the power rating to the ring-shaped member 7 of the substrate processing device 100 in advance.

The substrate processing system, the control method, and the control program which according to this disclosed embodiment time are illustrative in all points, and should be not understood as being restrictive. The embodiments may be modified and improved in various forms without departing from the scope of the appended claims and the principle thereof. The details described in the plurality of embodiments may take other configurations, and may be combined within a range that is not contradictory.

The substrate processing device of the present disclosure may be applied to any type of device among an atomic layer deposition (ALD) device, a capacitively coupled plasma (CCP) device, an inductively coupled plasma (ICP) device, a radial line slot antenna (RLSA) device, an electron cyclotron resonance plasma (ECR) device, and a helicon wave plasma (HWP) device.

In the above description, with respect to the DC voltage (FR V_{dc}) applied to the ring-shaped member 7, a method of preventing the application of the voltage outside the allowable range in advance was given as an example. However, the control method according to the present embodiment may be applied to a specific part in the processing container which applies the DC voltage other than the ring-shaped member 7. An example of the specific part in the processing container may be the upper electrode 3 formed of silicon or a silicon-containing material. That is, the control method according to the present embodiment may be used to determine the above-described recipe by setting the DC voltage applied to the upper electrode 3 as the FR V_{dc}, even when the DC voltage is applied from the DC power supply 72 to the upper electrode 3.

Further, even when the silicon-containing material is used for the sidewall of the processing container, the control method may be used for determination of the recipe in the case in which the DC voltage is applied to the sidewall of the processing container from a DC power supply (not shown).

1. A substrate processing system comprising:
a substrate processing device having a processing container configured to perform processing of a substrate, and a direct current (DC) power source configured to apply a DC voltage to a specific part in the processing container; and
a controller configured to control the substrate processing device,
wherein a process performed by the controller includes a process of acquiring desired process conditions and a real value of the DC voltage measured during processing of the substrate based on the process conditions, and
a process of creating a regression analysis equation which calculates an estimated value of the DC voltage using a plurality of conditions among the process conditions as explanatory variables based on the acquired process conditions and real value of the DC voltages.

2. The substrate processing system of claim 1, wherein the process performed by the controller includes:
a process of setting a threshold value corresponding to the created regression analysis equation;
a process of storing in a storage unit the regression analysis equation and the threshold value in correspondence with each other;
a process of inputting a condition used as the explanatory variables among the process conditions set in a desired recipe to the regression analysis equation, and calculating the estimated value of the DC voltage; and
a process of determining whether to employ the desired recipe based on whether the calculated estimated value of the DC voltage is a value within an allowable range based on the threshold value stored in the storage unit.

3. The substrate processing system of claim 2, wherein the process performed by the controller includes a process of storing the desired recipe in the storage unit when it is determined that the estimated value of the DC voltage is a value within the allowable range.

4. The substrate processing system of claim 3, wherein the process performed by the controller includes a process of outputting a warning when it is determined that the estimated value of the DC voltage is a value outside the allowable range.

5. The substrate processing system of claim 3, wherein the process performed by the controller includes a process of outputting at least one of the explanatory variables used for calculating the estimated value of the DC voltage when it is determined that the estimated value of the DC voltage is a value outside the allowable range.

6. The substrate processing system of claim 3, wherein the substrate processing device applies the DC voltage to the part in the processing container based on the recipe stored in the storage unit.

7. The substrate processing system of claim 2, wherein the process performed by the controller includes:
a process of setting a safety factor related to at least one of conditions not used as the explanatory variables among the process conditions set in the desired recipe;
a process of correcting the calculated estimated value of the DC voltage based on the set safety factor; and
a process of determining whether the corrected estimated value of the DC voltage is a value within the allowable range based on the threshold value stored in the storage unit.

8. The substrate processing system of claim 1, wherein the part in the processing container includes a ring-shaped member or an upper electrode disposed around the substrate.

9. A DC voltage control method of a substrate processing device having a processing container configured to perform processing of a substrate, and a DC power supply configured to apply a DC voltage to a specific part in the processing container, the method comprising:
a process of acquiring desired process conditions and a real value of the DC voltage measured during processing of the substrate based on the process conditions; and
a process of creating a regression analysis equation which calculates an estimated value of the DC voltage using a plurality of conditions among the process conditions as explanatory variables based on the acquired process conditions and real value of the DC voltage.

10. A DC voltage control program of a substrate processing device having a processing container configured to perform processing of a substrate, and a DC power supply configured to apply a DC voltage to a specific part in the processing container, the program comprising:
a process of acquiring desired process conditions and a real value of the DC voltage measured during processing of the substrate based on the process conditions; and
a process of creating a regression analysis equation which calculates an estimated value of the DC voltage using a plurality of conditions among the process conditions as explanatory variables based on the acquired process conditions and real value of the DC voltages.
